(19) United States
(12) Patent Application Publication
(10) Pub. No.: US 2017/0233864 A1
(43) Pub. Date: Aug. 17, 2017

(54) METAL DEPOSITION SOURCE ASSEMBLY AND DEPOSITING APPARATUS INCLUDING THE SAME

(71) Applicant: Samsung Display Co., Ltd., Yongin-si (KR)

(72) Inventors: Jinwoo PARK, Yongin-si (KR); Jungho PARK, Yongin-si (KR); Suhwan LEE, Yongin-si (KR)

(21) Appl. No.: 15/433,362

(22) Filed: Feb. 15, 2017

(30) Foreign Application Priority Data
Feb. 15, 2016 (KR) 10-2016-0017221

(51) Int. Cl. C23C 16/06; C23C 16/46

(52) U.S. Cl. CPC C23C 16/06; C23C 16/46

(57) ABSTRACT

A metal deposition source assembly includes a housing, a crucible disposed inside the housing, a heater disposed between the housing and the crucible, a nozzle disposed at an upper portion of the housing, and a bead layer disposed inside the crucible, the bead layer including a plurality of beads.

### CROSS-REFERENCE TO RELATED APPLICATION

This application claims priority from and the benefit of Korean Patent Application No. 10-2016-0017221, filed on Feb. 15, 2016, which is hereby incorporated by reference for all purposes as if fully set forth herein.

### BACKGROUND

Field

Exemplary embodiments relate to a metal deposition source assembly and a metal depositing apparatus including the same.

Discussion of the Background

An organic light-emitting display apparatus including a thin film transistor (TFT) is used in a mobile apparatus, such as a smart phone, a tablet personal computer, a laptop computer, a digital camera, a camcorder, a potable information terminal, etc., and an electronic apparatus, such as a desktop computer, a television, a billboard, etc.

The organic light-emitting display apparatus includes an anode and a cathode, which are disposed on a substrate, and an organic light-emitting layer, which is disposed between the anode and the cathode. A thin film, such as the anode, the cathode, and the organic light-emitting layer, is formed by using a deposition process. Particularly, a metal thin film layer, such as the anode and the cathode, is formed by using a deposition process of vaporizing a deposition material in a metal deposition source assembly, which contains the deposition material, and then depositing the vaporized deposition material on the substrate.

However, in a conventional metal deposition source assembly, a deposition material in a liquid state moves toward a nozzle or a substrate and is then solidified on the nozzle or the substrate. Thus, a dark spot is formed on a panel of a display apparatus.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments include a metal deposition source assembly and a metal depositing apparatus including the same.

Additional aspects will be set forth in part in the detailed description which follows and, in part, will be apparent from the disclosure, or may be learned by practice of the inventive concept.

An exemplary embodiment discloses a metal deposition source assembly. The metal deposition source assembly includes a housing, a crucible disposed inside the housing, a heater disposed between the housing and the crucible, a nozzle disposed at an upper portion of the housing, and a bead layer disposed inside the crucible. The bead layer includes a plurality of beads.

An exemplary embodiment discloses a metal depositing apparatus. The metal depositing apparatus includes a chamber, a metal deposition source assembly, and a blocking mask disposed inside the chamber. The metal deposition source assembly includes a housing disposed inside the chamber, a crucible disposed inside the housing, a heater disposed between the housing and the crucible, a nozzle disposed at an upper portion of the housing, and a bead layer including a plurality of beads.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view schematically illustrating a metal deposition source assembly according to an exemplary embodiment.

FIGS. 2A and 2B are enlarged cross-sectional views of portion “A” of FIG. 1.

FIG. 3 is a plan view illustrating an inner plate of the metal deposition source assembly of FIG. 1.

FIG. 4 is a cross-sectional view schematically illustrating a metal deposition source assembly according to an exemplary embodiment.

FIG. 5 is a plan view illustrating a mesh plate of the metal deposition source assembly of FIG. 4.

FIG. 6 is a cross-sectional view schematically illustrating an exemplary embodiment of a metal depositing apparatus including the metal deposition source assembly of FIG. 1.

FIG. 7 is a plan view illustrating an exemplary embodiment of a display apparatus manufactured by the metal depositing apparatus of FIG. 6.

FIG. 8 is a cross-sectional view taken along a line VIII-VIII′ of FIG. 7.

### DETAILED DESCRIPTION THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

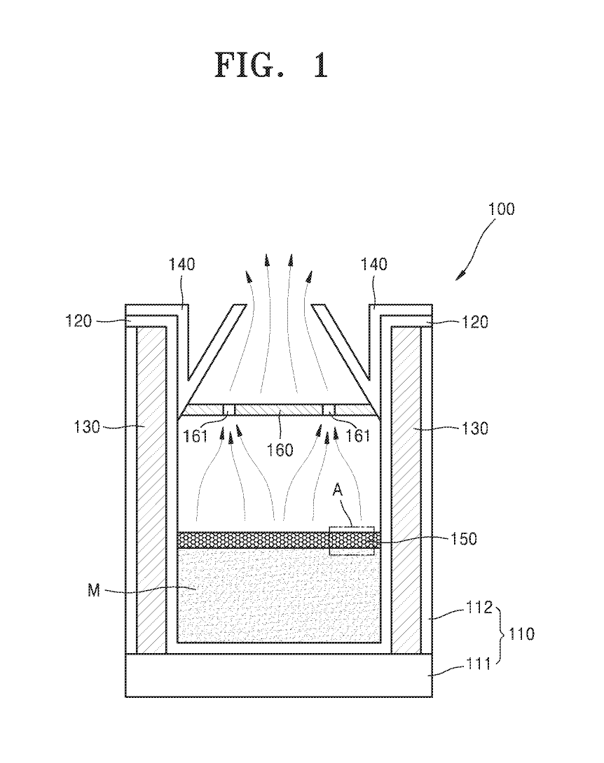

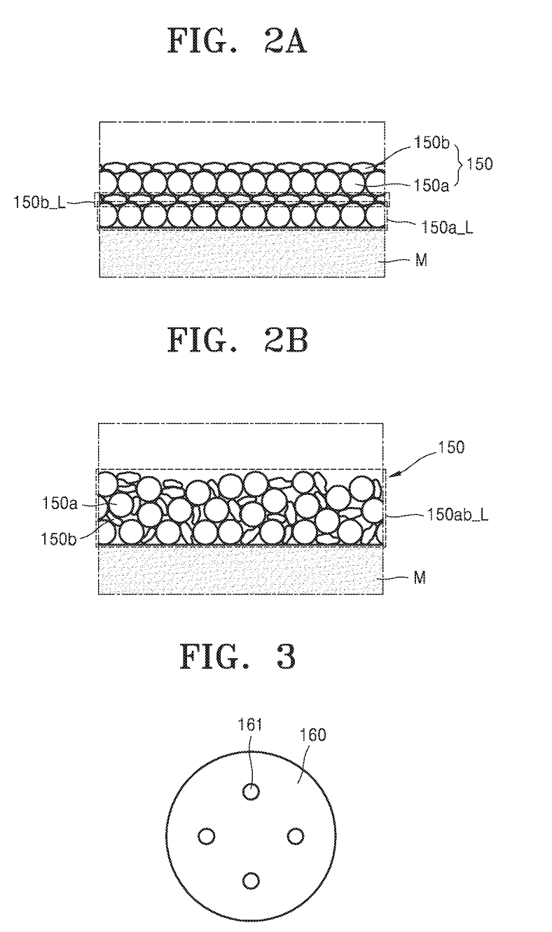

FIG. 1 is a cross-sectional view schematically illustrating a metal deposition source assembly 100 according to an exemplary embodiment. FIGS. 2A and 2B are enlarged cross-sectional views of a portion “A” of FIG. 1. FIG. 3 is a plan view illustrating an inner plate 160 of the metal deposition source assembly 100 of FIG. 1.

Referring to FIG. 1, the metal deposition source assembly 100 may include a housing 110, a crucible 120, a heater 130, a nozzle 140, a bead layer 150, and an inner plate 160.

The housing 110 may include a bottom housing 111, which forms a bottom of the metal deposition source assembly 100, and a side housing 112, which forms a side of the metal deposition source assembly 100.

Although not illustrated in the drawings, the bottom housing 111 may have any shape in plan view. For example, the bottom housing 111 may have a circular, elliptical, or polygonal shape. Also, depending on the shape of the bottom housing 111, the side housing 112 may have a corresponding shape. That is, according to an exemplary embodiment, if the bottom housing 111 has a circular shape, the side housing 112 may be a hollow circular plate corresponding to the shape of the bottom housing 111. However, the present disclosure is not limited thereto. According to another exemplary embodiment, if the bottom housing 111 has a polygonal shape, the side housing 112 may include a plurality of plates connected to each other to correspond to the shape of the bottom housing 111. For convenience, a case in which the bottom housing 111 has a circular shape will be explained in detail hereinafter.

The crucible 120 may be installed inside the housing 110 and may accommodate a deposition material M, which is a raw material for forming a metal thin film and is to be deposited on a substrate (not illustrated). The crucible 120 may include a material having a high thermal conductivity such that heat generated by the heater 130 is effectively transmitted to the crucible 120.

The heater 130 may be installed between the housing 110 and the crucible 120. The heater 130 may heat the crucible 120. Heat transmitted from the heater 130 to the crucible 120 may be used for vaporizing the deposition material in a liquid or solid state.

The nozzle 140 may be installed on an upper portion of the housing 110 and may guide the vaporized deposition material M to be ejected toward a substrate through an opening thereof. Although the drawing illustrates that the metal deposition source assembly includes a single nozzle 140, the present disclosure is not limited thereto. That is, the metal deposition source assembly 100 may include a plurality of nozzles 140. However, a case in which the metal deposition source assembly 100 includes the single nozzle 140 will be explained in detail hereinafter.

The bead layer 150 may be installed over the deposition material M and may include a plurality of beads 150a and a plurality of beads 150b so that the vaporized deposition material M passes through spaces formed between the pluralities of beads 150a and 150b. The plurality of beads 150a may be different from the plurality of beads 150b.

The inner plate 160 may be fixedly installed to an inside circumferential surface of the crucible 120 and may include a plurality of through holes 161 through which the deposition material M passes. The inner plate 160 may block a portion of the deposition material M before the vaporized deposition material M passes through the nozzle 140.

In detail, if the bead layer 150 is not included in the metal deposition source assembly 100, the through holes 161 of the inner plate 160 may have a size sufficient to allow the deposition material M in a liquid state to pass therethrough. That is, the though holes 161 of the inner plate 160 may have a size sufficient to allow for the vaporized deposition material M to be deposited on the substrate. The number of the though holes 161 of the inner plate 160 is not limited to four (4) as illustrated in FIG. 3. The inner plate 160 may include a plurality of through holes.

Referring to FIGS. 2A and 2B, the plurality of beads 150a may have a spherical shape and the plurality of beads 150b may have an atypical shape. The bead layer 150 may include only the plurality of beads 150a of the spherical shape or only the plurality of beads 150b of the atypical shape. Moreover, the bead layer 150 may include a combination of the plurality of beads 150a of the spherical shape and the plurality of beads 150b of the atypical shape as illustrated in the drawings.

In detail, the bead layer 150 may include at least one of a first layer 150a_L including the plurality of beads 150a of the spherical shape, a second layer 150b_L including the plurality of beads 150b of the atypical shape, and a combination layer 150ab_L including a mix of the plurality of beads 150a of the spherical shape and the plurality of beads 150b of the atypical shape, as illustrated in FIGS. 2A and 2B.

Although not illustrated in the drawings, the bead layer 150 may include the first layer 150a_L including the plurality of beads 150a of the spherical shape only, or the second layer 150b_L including the plurality of beads 150b of the atypical shape only. Moreover, the bead layer 150 may include a combination structure which includes the combination layer 150ab_L including a mix of the plurality of beads 150a of the spherical shape and the plurality of beads 150b of the atypical shape as illustrated in FIG. 2B, the first layer 150a_L as illustrated in FIG. 2A, and the second layer 150b_L as illustrated in FIG. 2A.

Although FIG. 2A illustrates the first layer 150a_L and the second layer 50b_L, which include the plurality of beads 150a of the spherical shape and the plurality of beads 150b of the atypical shape, respectively, and FIG. 2B illustrates the combination layer 150ab_L, which is a mix of the plurality of beads 150a of the spherical shape and the plurality of beads of the atypical shape, FIGS. 2A and 2B illustrate simple examples only for convenience and the present disclosure is not limited thereto. That is, the plurality of beads 150a of the spherical shape and the plurality of beads 150b of the atypical shape may have a different shape in the bead layer 150 as long as the bead layer 150 is over the deposition material M.

The bead layer 150 may include the plurality of beads 150a and the plurality of 150b having a lower density than a density of the deposition material so that the plurality of beads 150a and the plurality of beads 150b float over the deposition material M. In detail, the plurality of beads 150a and the plurality of beads 150b of the bead layer 150 may include one or more of silicon (Si), silicon carbide (SiC), and tantalum (Ta), for example.

As illustrated in FIGS. 2A and 2B, an arrangement of the bead layer 150 over the deposition material M may have the following effects.

Generally, the deposition material M of the metal deposition source assembly 100 may include at least one of silver (Ag), magnesium (Mg), and ytterbium (Yb). All of the silver (Ag), magnesium (Mg), and ytterbium (Yb) are metals. Vapors may be generated at a contact surface between the deposition material M and the crucible 120 during a process of heating the deposition material M by the heater 130 to change the deposition material M from a solid state into a liquid state and a vapor state. The vapors may move up in an upward direction and may be discharged toward an abutting area between the deposition material M and the bead layer 150, and a splash phenomenon may occur such that a portion of the deposition material M, which has not vaporized yet and is in a liquid state, may bounce off toward the substrate or the nozzle 140.

If a metal deposition source assembly does not include the bead layer 150, the above-described splash phenomenon may not be prevented. Accordingly, the deposition material M, which bounces off toward the substrate in the metal deposition source assembly without the bead layer 150, may be stacked on the substrate as a larger mass instead of fine particles occurring by vaporization of the deposition material M in the metal deposition source assembly 100. In this case, when an organic layer is formed during a process of depositing an organic material after the metal is deposited on the substrate by using the metal depositing source assembly without the bead layer 150, the organic layer is damaged and a current may not flow through the damaged organic layer when a display apparatus is manufactured. Thus, a dark spot may be generated in a display panel of the display apparatus.

Moreover, when the deposition material M bounces off toward the nozzle 140 due to the splash phenomenon, a material-growing phenomenon may occur in which the deposition material M is continuously deposited on the nozzle 140 and then the continuously-deposited deposition material M may block a passage of the deposition material M. When the material-growing phenomenon occurs at an outlet of the nozzle 140, the vaporized deposition material M is congested inside the crucible 120, and then an inner pressure of the crucible 120 increases. If these phenomena continue, the metal deposition source assembly 100 without the bead layer 150 may explode.

However, the metal deposition source assembly 100 according to an exemplary embodiment may prevent the splash phenomenon that occurs when the deposition material M bounces off toward the substrate and the nozzle 140.

In detail, minute spaces may be formed between the adjacent beads 150a and 150b of the bead layer 150. The vaporized deposition material M may pass through the minute spaces and move to an upper portion of the metal deposition source assembly 100.

When a portion of the deposition material M, which has not vaporized yet and is still in a liquid state, bounces off in an upward direction, the bead layer 150, which is above the deposition material M, may effectively prevent bouncing of the above-described bouncing portion of the deposition material M.

That is, the bead layer 150 may prevent the bouncing of the deposition material M in the liquid state in the upward direction toward the substrate or nozzle 140, and also may allow the deposition material M in a gaseous state to pass through the minute spaces of the plurality of beads 150a and the plurality of beads 150b toward the substrate. The deposition material M in the gaseous state, which passes through the bead layer 150, may move in a solid direction of FIG. 1 and be ejected toward the substrate.

Moreover, the bead layer 150 may prevent a heat loss of the crucible 120. Thus, the deposition material M may reach a melting point faster in the metal deposition source assembly 100 with the bead layer 150 than in a metal deposition source assembly without the bead layer 150. Furthermore, the deposition material M may be completely melted in the metal deposition source assembly 100, which increases a deposition efficiency of the metal deposition source assembly 100.

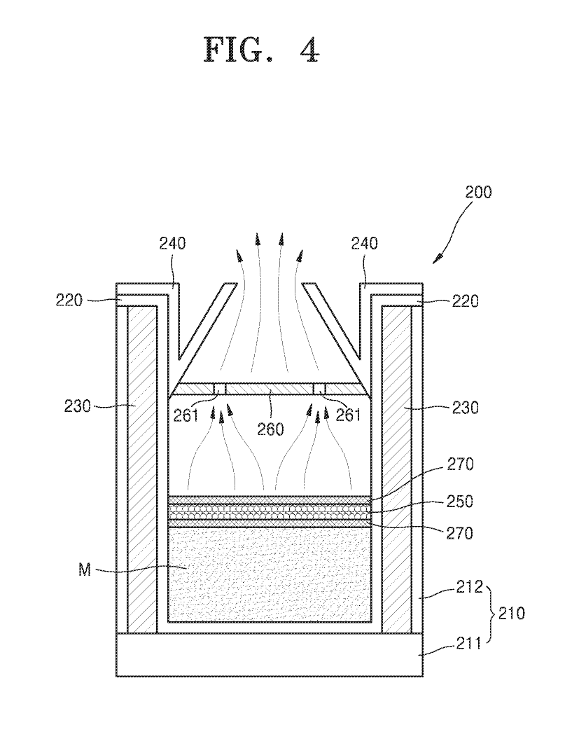

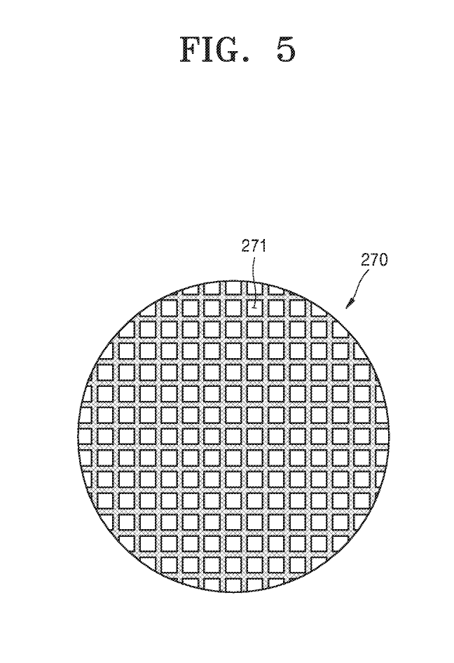

FIG. 4 is a cross-sectional view schematically illustrating a metal deposition source assembly 200 according to an exemplary embodiment. FIG. 5 is a plan view illustrating a mesh plate 270 of the metal deposition source assembly 200 of FIG. 4.

Referring to FIG. 4, the metal deposition source assembly 200 according to an exemplary embodiment includes a housing 210, a crucible 220, a heater 230, a nozzle 240, a bead layer 250, an inner plate 260, and the mesh plate 270.

Components of the metal deposition source assembly 200 may be same as or similar to the metal deposition source assembly 100 of FIG. 1, except for the mesh plate 270. Descriptions of the component of the metal deposition source assembly 200 except the mesh plate 270 may be inferred from the descriptions of the components of the metal deposition source assembly 100.

The metal deposition source assembly 200 may include a plurality of mesh plates 270 above and below the bead layers 250, as illustrated in FIG. 4.

Each of the mesh plates 270 may include a plurality of openings 271 arranged in a matrix form as shown in FIG. 5. The mesh plates 270 above the deposition material M may effectively prevent the above-described splash phenomenon together with the bead layer 250.

Moreover, the mesh plates 270 below the bead layer 250 may prevent precipitation of the liquidized deposition material M back into a solid state. Furthermore, when an inside of the crucible 220 is washed, the bead layer 250 may be easily separated from the deposition material M because of the mesh plates 200 below the bead layer 250. Thus, the inside of the crucible 220 may be easily washed due to the easy separation of the bead layer 250 from the crucible 220.

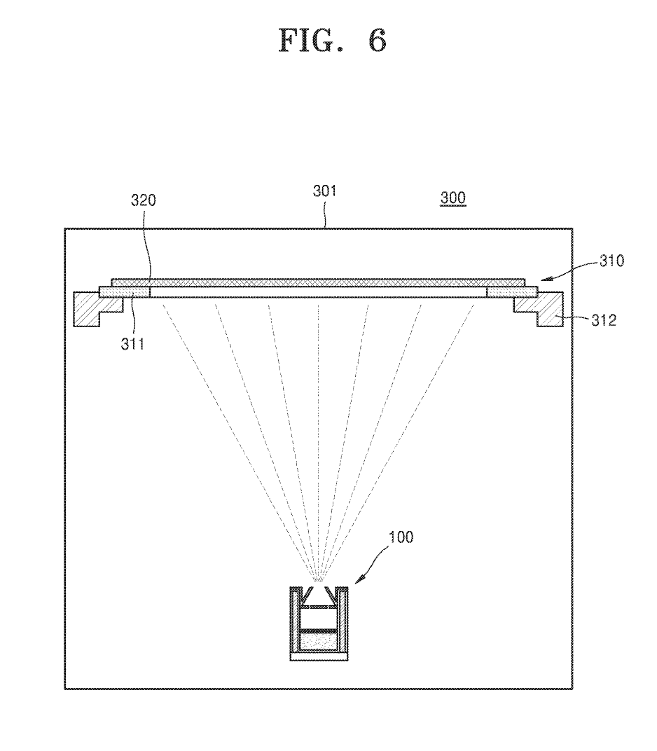

FIG. 6 is a cross-sectional view schematically illustrating a metal depositing apparatus 300 including the metal deposition source assembly 100 of FIG. 1.

Referring to FIG. 6, the metal depositing apparatus 300 may include a chamber 301, the metal deposition source assembly 100, and a blocking mask 311.

The chamber 301 may be a vacuum chamber in which a metal thin film is deposited on a substrate 320 of an organic light-emitting display apparatus.

A blocking mask assembly 310 may be installed at an upper portion of the chamber 301. The blocking mask assembly 310 may include the blocking mask 311 and a holder 312 to fixedly couple the blocking mask 311 thereto.

In detail, the blocking mask 311 may be installed between the substrate 320 and the metal deposition source assembly 100. The blocking mask 311 may be a frame having a center opening to block a portion of the deposition material M, which is ejected from the metal deposition source assembly 100 toward an outermost circumference of the substrate 320, from among the deposition material M which is ejected from the metal deposition source assembly 100.

The metal deposition source assembly 100 of FIG. 1 may be arranged at a lower portion of the chamber 301. Although not illustrated in the drawing, the metal deposition source assembly 200 of FIG. 4 may be arranged at the lower portion of the chamber 301.

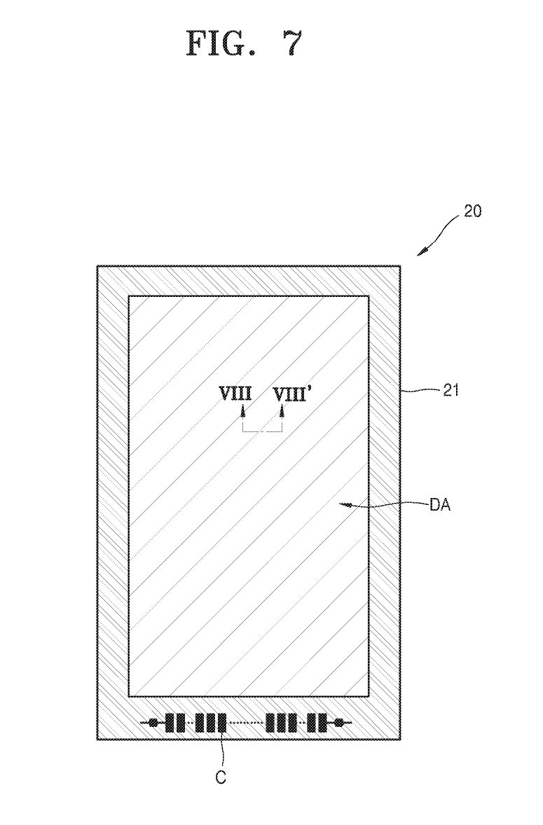

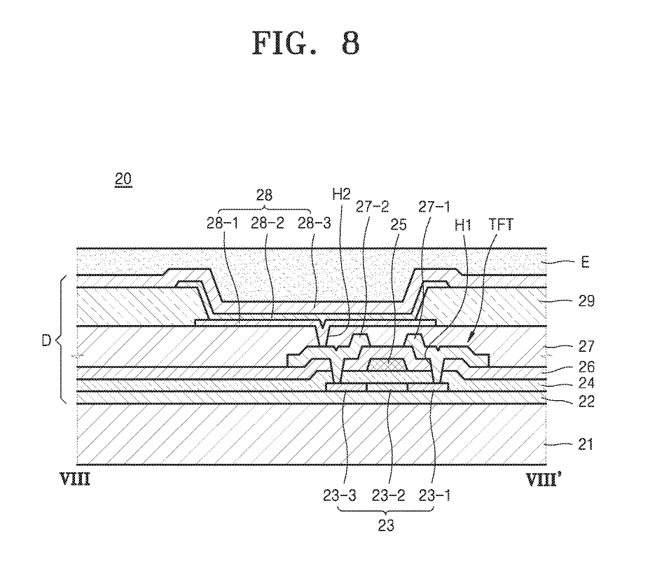

FIG. 7 is a plan view illustrating a display apparatus 20 manufactured by the metal depositing apparatus 300 of FIG. 6. FIG. 8 is a cross-sectional view taken along a line VIII-VIII′ of FIG. 7.

Referring to FIGS. 7 and 8, the display apparatus 20 may include a display area DA, which is above a substrate 21, and a non-display area (not illustrated) at an outer circumference of the display area DA. A light-emitting portion D is arranged in the display area DA, and power wirings (not illustrated) are arranged in the non-display area. A pad area C may be arranged in the non-display area.

The display apparatus 20 may include the substrate 21 and the light-emitting portion D. Also, the display apparatus 20 may include an encapsulating layer E over an upper portion of the light-emitting portion D. The substrate 21 may include a plastic material or a metal, such as stainless steel (SUS), titanium (Ti), etc. The substrate 21 may also include polyimide (PI). For convenience, a case in which the substrate 21 includes the PI will be explained in detail hereinafter.

The light emitting portion D may be disposed over the substrate 21. The light emitting portion may include a thin film transistor TFT, a passivation film 27 to cover the thin film transistor TFT, and an organic light-emitting device (OLED) 28 over the passivation film 27.

The substrate 21 may include a glass material. However, the present disclosure is not limited thereto. The substrate 21 may include a plastic material or a metal such as SUS, Ti, etc. The substrate 21 may also include the PI. For convenience, a case in which the substrate 21 includes a glass material will be explained in detail hereinafter.

A buffer layer 22 may be over an upper surface of the substrate 21 and may include an organic compound and/or an inorganic compound. The buffer layer 22 may include silicon oxide (SiOx), wherein x≧1, or silicon nitride (SiNx), wherein x≧1.

After an active layer 23 is formed as a plurality of patterns over the buffer layer 22, the active layer 23 is covered by a gate insulating layer 24. The active layer 23 may include a source area 23-1, a drain area 23-3, and a channel area 23-3 between the source area 23-1 and the drain area 23-3.

The active layer 23 may include various materials. For example, the active layer 23 may include an inorganic semiconductor material, such as amorphous silicon or crystal silicon. Alternatively, the active layer 23 may include an organic semiconductor material. However, for convenience, a case in which the active layer 23 includes amorphous silicon will be explained in detail hereinafter.

The active layer 23 may be formed by forming the amorphous silicon over the buffer layer 22, crystalizing the amorphous silicon to form a polycrystalline, and patterning the polycrystalline. The active layer 23 may include the source area 23-1 and the drain area 23-3 which are formed by doping the active layer 23 with impurities according to a kind of the thin film transistor TFT, such as a driving thin film transistor (not illustrated) and a switching thin film transistor (not illustrated).

A gate electrode 25 is formed over the gate insulating layer 24 to correspond to the channel region 23-2 of the active layer 23, and then an interlayer insulating layer 26 is formed to cover the gate electrode 25.

After a contact hole H1 is formed in the interlayer insulating layer 26 and the gate insulating layer 24, a source electrode 27-1 and a drain electrode 27-2 are formed over the interlayer insulating layer 26 and contact the source area 23-1 and the drain area 23-3, respectively.

A passivation film 27 may be formed over the thin film transistor TFT, and a pixel electrode 28-1 of the organic light-emitting device OLED may be formed over the passivation film 27. The pixel electrode 28-1 may contact the drain electrode 27-2 of the thin film transistor TFT through a via hole H2 formed in the passivation film 27. The passivation film 27 may include an inorganic material, an organic material, a single layer, or a multilayer having two or more layers. The passivation film 27 may be a planarization film having a flat upper film surface regardless of a curved lower film surface thereof. However, the passivation film 27 may have a curved upper film surface according to the curved lower film surface. The passivation film 27 may include a transparent insulating material to attain resonance effects.

After the pixel electrode 28-1 is formed over the passivation film 27, a pixel defining film 29 is formed to cover the pixel electrode 28-1. The pixel defining film 29 includes an organic material and/or an inorganic material and exposes a surface of the pixel electrode 28-1.

Also, an intermediate layer 28-2 and an opposite electrode 28-3 are formed over the pixel electrode 28-1.

The pixel electrode 28-1 may function as an anode and the opposite electrode 28-3 may function as a cathode. According to an exemplary embodiment, polarities of the pixel electrode 28-1 and the opposite electrode 28-3 may be reversed.

The pixel electrode 28-1 and the opposite electrode 28-3 may be insulated from each other by the intermediate layer 28-2, and voltages with different polarities may be applied to the intermediate layer 28-2 such that light is emitted from an organic emission layer.

The intermediate layer 28-2 may include the organic emission layer. In an exemplary embodiment, the intermediate layer 28-2 may include the organic emission layer and additionally include at least one of a hole injection layer (HIL), a hole transport layer (HTL), an electron transport layer (ETL), and an electron injection layer (EIL). However, the present disclosure is not limited thereto. The intermediate layer 28-2 may include the organic emission layer and additionally include various functional layers (not illustrated).

The intermediate layer 28-2 may be formed in an apparatus (not illustrated) to manufacture the display apparatus 20 described above.

A unit pixel may include a plurality of sub-pixels, and the plurality of sub-pixels may respectively emit various different colors of light. For example, the plurality of sub-pixels may include sub-pixels respectively emitting a red color light, a green color light, and a blue color light or sub-pixels respectively emitting the red color light, the green color light, the blue color light, and a white color light.

The encapsulating layer E may include a plurality of inorganic layers or may include an inorganic layer and an organic layer.

The organic layer of the encapsulating layer E may include a polymer. The organic layer of the encapsulating layer E may include a single film or a stack film including at least one of polyethylene terephthalate, polyimide, polycarbonate, epoxy, polyethylene, and polyacrylate. The organic layer of the encapsulating layer E may include polyacrylate. The organic layer of the encapsulating layer E may include a diacrylate-based monomer or a polymerized monomer compound including the diacrylate-based monomer. A monoacrylate-based monomer may be added to the monomer compound. Also, a photoinitiator, such as 2,4,6-trimethylbenzoyl-diphenyl-phosphineoxide (TPO), may be added to the monomer compound. However, the present disclosure is not limited thereto.

The inorganic layer of the encapsulating layer E may include a single film or a stack film, which may include a metal oxide or metal nitride. The inorganic layer of the encapsulating layer E may include at least one of silicon nitride (SiNx), aluminum oxide (Al₂O₃), silicon oxide (SiO₂), and titanium oxide (TiO₂).

An uppermost layer of the encapsulating layer E may include an inorganic layer to prevent penetration of moisture into the organic light-emitting device (OLED).

The encapsulating layer E may include at least one sandwich structure in which at least one organic layer is inserted between at least two inorganic layers. In an exemplary embodiment, the encapsulating layer E may include at least one sandwich structure in which at least one inorganic layer is inserted between at least two organic layers. In another embodiment, the encapsulating layer E may include at least one sandwich structure in which at least one organic layer is interposed between at least two inorganic layers, and at least one sandwich structure in which at least one inorganic layer is interposed between at least two organic layers.

The encapsulating layer E may include a first inorganic layer, a first organic layer, and a second inorganic layer, which are disposed in the stated order from an upper portion of the organic light-emitting device (OLED).

The encapsulating layer E may include a first inorganic layer, a first organic layer, a second inorganic layer, a second organic layer, and a third inorganic layer, which are disposed in the stated order from the upper portion of the organic light-emitting device (OLED).

The encapsulating layer E may include a first inorganic layer, a first organic layer, a second inorganic layer, a second organic layer, a third inorganic layer, a third organic layer, and a fourth inorganic layer, which are disposed in the stated order from the upper portion of the organic light-emitting device (OLED).

A halogenated metal layer including lithium fluoride (LiF) may be added between the organic light-emitting device (OLED) and the first inorganic layer of the encapsulating layer E. The halogenated metal layer may prevent damage of the organic light-emitting device (OLED) during forming the first inorganic layer by using a sputtering method.

An area of the first organic layer may be less than an area of the second inorganic layer, and an area of the second organic layer may be less than an area of the third inorganic layer.

Accordingly, since the display apparatus 20 includes the intermediate layer 28-2 having a precise pattern and the intermediate layer 28-2 is deposited and formed at an accurate location of the display apparatus 20, a precise image may be realized by the display apparatus. Moreover, a consistent pattern may be maintained in the display apparatus 20 so that uniform quality may be achieved in production when the intermediate layer 28-2 is repeatedly deposited in the display apparatus 20.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A metal deposition source assembly, comprising:
a housing;
a crucible disposed inside the housing;
a heater disposed between the housing and the crucible;
a nozzle disposed at an upper portion of the housing; and
a bead layer disposed inside the crucible and comprising a plurality of beads.

2. The metal deposition source assembly of claim 1, wherein:
the heater is configured to heat the crucible,
the crucible is configured to accommodate a deposition material comprising one or more of silver (Ag), magnesium (Mg), and ytterbium (Yb),
the nozzle is configured to guide the deposition material in a vaporized state along an ejection path toward a substrate, and
the bead layer disposed over the deposition material.

3. The metal deposition source assembly of claim 1, wherein the plurality of beads have at least one of a spherical shape and an atypical shape.

4. The metal deposition source assembly of claim 1, wherein the bead layer comprises at least one of a first layer comprising a plurality of beads having a spherical shape, a second layer comprising a plurality of beads having an atypical shape, and a combination layer comprising the plurality of beads having the spherical shape and the plurality of beads having the atypical shape.

5. The metal deposition source assembly of claim 1, wherein a density of the plurality of beads is less than a density of a deposition material disposed below the plurality of beads.

6. The metal deposition source assembly of claim 1, wherein the plurality of beads comprise at least one of silicon (Si), silicon carbide (SiC), and tantalum (Ta).

7. The metal deposition source assembly of claim 1, further comprising: an inner plate disposed inside the crucible and comprising a plurality of through holes.

8. The metal deposition source assembly of claim 1, further comprising:
a mesh plate disposed above, the bead layer, below the bead layer, or above and below the bead layer, the mesh plate comprising a plurality of openings.

9. A metal depositing apparatus, comprising:
a chamber;
a metal deposition source assembly comprising:
a housing disposed inside the chamber;
a crucible disposed inside the housing;
a heater disposed between the housing and the crucible;
a nozzle disposed at an upper portion of the housing; and
a bead layer disposed inside the crucible, the bead layer comprising a plurality of beads; and
a blocking mask disposed inside the chamber.

10. The metal deposition source assembly of claim 9, wherein:
the crucible is configured to accommodate a deposition comprising one or more of silver (Ag), magnesium (Mg), and ytterbium (Yb),
the heater is configured to heat the crucible,
the nozzle is configured to guide the deposition material in a vaporized state long an ejection path toward a substrate,
the bead layer is configured to allow the deposition material to pass through, and
the blocking mask is disposed between the metal deposition source assembly and the substrate, the blocking mask is configured to block a portion of the deposition material ejected from the metal deposition source assembly toward an outermost circumference of the substrate.

11. The metal deposition source assembly of claim 9, wherein the plurality of beads have at least one of a spherical shape and an atypical shape.

12. The metal deposition source assembly of claim 9, wherein the bead layer comprises at least one of a first layer comprising a plurality of beads having a spherical shape, a second layer comprising a plurality of beads having an atypical shape, and a combination layer comprising the plurality of beads having the spherical shape and the plurality of beads having the atypical shape.

13. The metal deposition source assembly of claim 9, wherein a density of the plurality of beads is less than a density of a deposition material disposed below the plurality of beads.

14. The metal deposition source assembly of claim 9, wherein the plurality of beads comprise at least one of silicon (Si), silicon carbide (SiC), and tantalum (Ta).

15. The metal deposition source assembly of claim 9, further comprising:
an inner plate disposed inside the crucible, the inner plate comprising a plurality of through holes.

16. The metal deposition source assembly of claim 9, further comprising:
a mesh plate disposed above the bead layer, below the bead layer, or above and below the bead layer, the mesh plate comprising a plurality of openings.
